(19) United States
(12) Patent Application Publication
(10) Pub. No.: US 2013/0082282 A1
(43) Pub. Date: Apr. 4, 2013

(54) SILICON CARBIDE SEMICONDUCTOR DEVICE

(71) Applicant: Takuma SUZUKI, Kanagawa (JP)

(72) Inventor: Takuma SUZUKI, Kanagawa (JP)

(73) Assignee: Kabushiki Kaisha Toshiba, Tokyo (JP)

(21) Appl. No.: 13/412,909

(22) Filed: Mar. 6, 2012

(30) Foreign Application Priority Data
Sep. 30, 2011 (JP) 2011-217802

(51) Int. Cl. H01L 29/38

(52) U.S. Cl. 257/77; 257/E29.105

(57) ABSTRACT

Disclosed is a semiconductor device which includes a silicon carbide layer, a trench formed in the silicon carbide layer, and a channel formed on at least one of a bottom of the trench, a side-wall surface, or the silicon carbide layer, in which an electrical conduction direction of the channel is parallel to a surface of the silicon carbide layer.

### CROSS-REFERENCE TO RELATED APPLICATION

This application is based upon and claims the benefit of priority from the prior Japanese Patent applications No. JP2011-217802, filed on Sep. 30, 2011; the entire contents of which are incorporated herein by reference.

### FIELD

Embodiments described herein relate generally to a semiconductor device using silicon carbide (SiC).

### BACKGROUND

Silicon carbide (hereinafter, referred to as SiC) is anticipated to become a material of the next-generation power semiconductor devices. Compared to Si, SiC has excellent material properties, for example, about 3 times bandgap, about 10 times breakdown field strength, and about 3 times thermal conductivity. With the properties well used, power semiconductor devices operable at a high temperature with an ultralow loss can be implemented.

Examples of high-voltage semiconductor device using the properties of SiC include a vertical type of metal insulator semiconductor field effect transistor (MISFET) and an insulated gate bipolar transistor (IGBT). In order to enhance the device performance of the MISFET or IGBT, it is required to increase channel mobility so as to implement low on-resistance.

### BRIEF DESCRIPTION

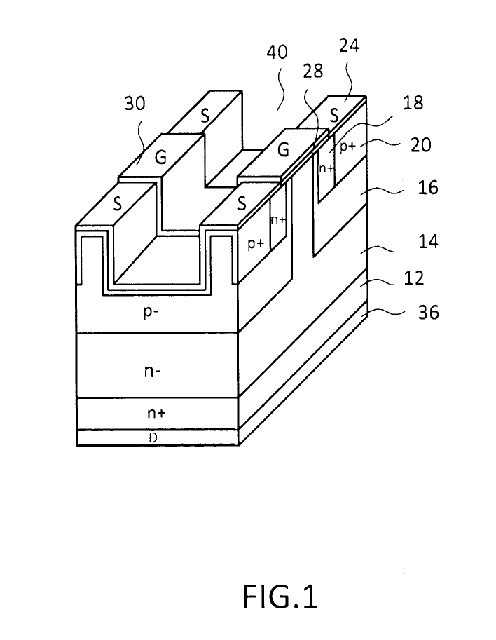

FIG. 1 is a perspective view illustrating a configuration of a MISFET of Example 1;

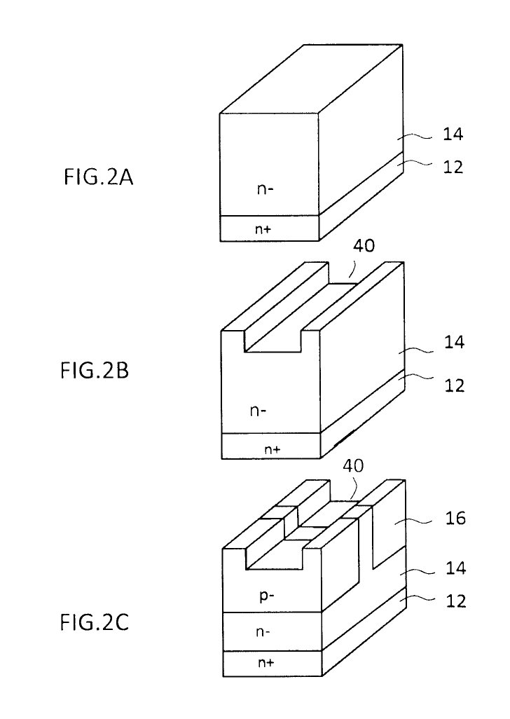

FIGS. 2A to 2C are process perspective views illustrating a method of manufacturing a semiconductor device of Example 1;

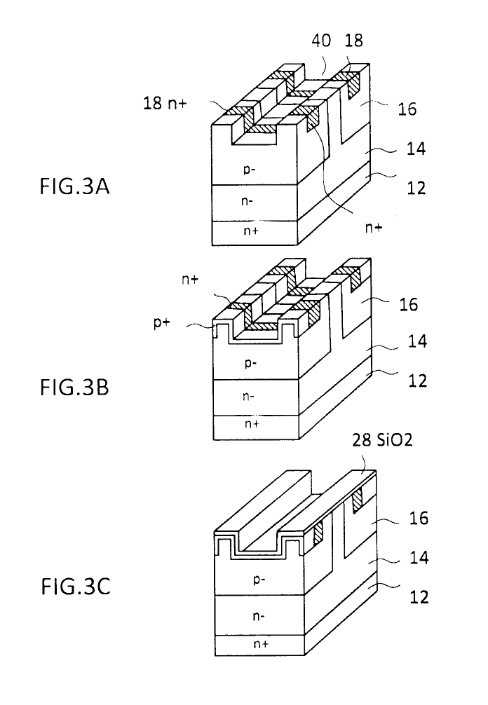

FIGS. 3A to 3C are process perspective views illustrating the method of manufacturing the semiconductor device of Example 1;

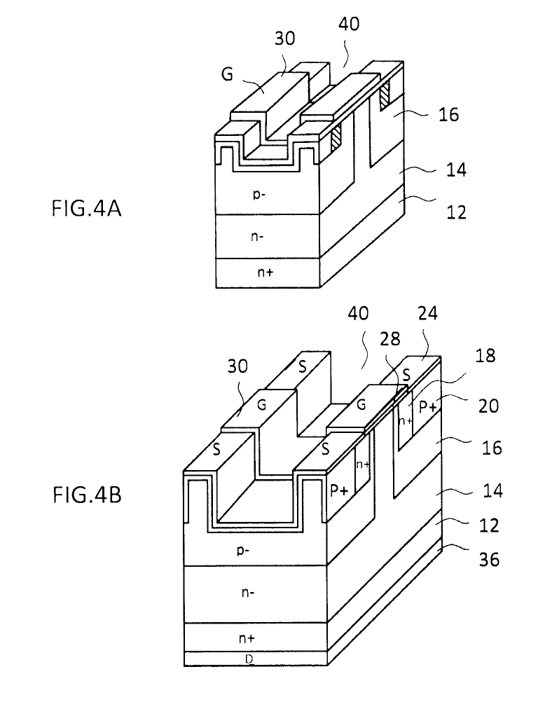

FIGS. 4A and 4B are process perspective views illustrating the method of manufacturing the semiconductor device of Example 1;

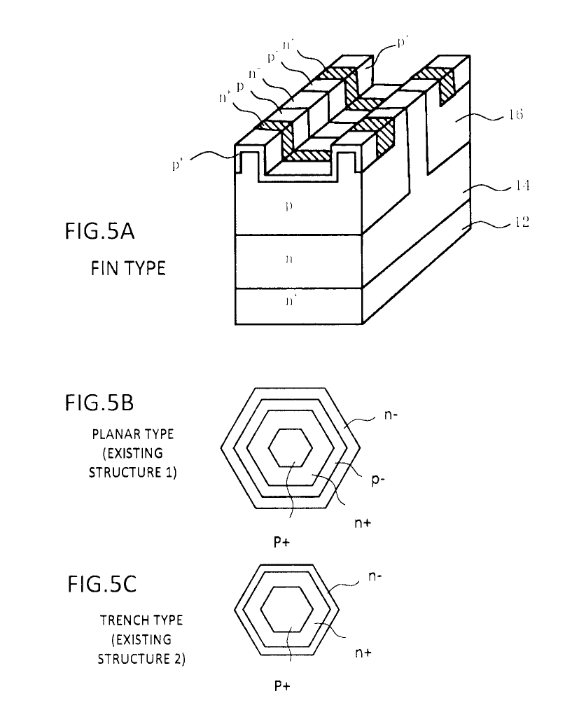

FIGS. 5A to 5C are schematic diagrams illustrating a result of comparison between the semiconductor device according to an embodiment, a unit cell structure of the semiconductor device of the related art, a channel width per unit cell area, and an effective inversion channel mobility; and

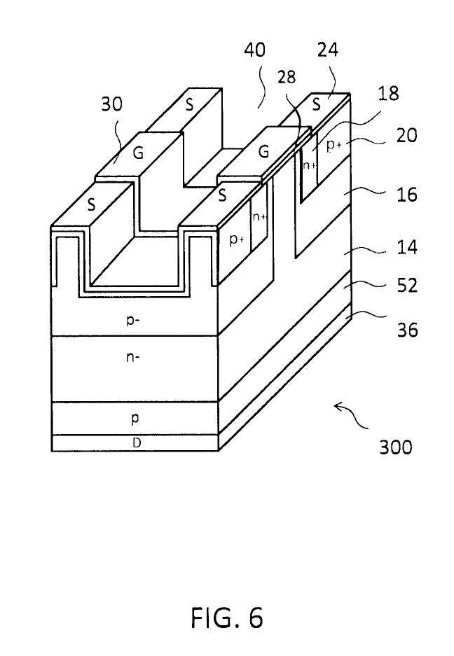

FIG. 6 is a perspective view illustrating a configuration of an IGBT as a semiconductor device of Example 2.

### DETAILED DESCRIPTION OF THE INVENTION

In order to obtain a high performance device, it is necessary to further improve the channel mobility, reduce a size of the unit cell, or increase a gate width of a unit cell. In addition, it is also necessary to improve reliability of a gate insulation film.

Embodiments have been made in view of the above problem, and it is an object to provide a semiconductor device having low on-resistance and excellent reliability using SiC and a method of manufacturing the same.

The semiconductor device according to the present embodiment includes a silicon carbide layer, a trench formed in the silicon carbide layer, and a channel formed on a side-wall surface of a trench. The channel enables conduction of electricity in parallel to the surface of the silicon carbide layer.

Hereinafter, how the present embodiment is achieved is described.

As described above, in order to obtain a high device performance in a MISFET or IGBT using SiC, it is required to increase channel mobility so as to implement low on-resistance.

First of all, an interface state is easily formed at an interface between SiC and a gate insulation film formed on the SiC, particularly, at an interface between SiC and a thermal oxidation film. For this reason, problematically, the channel mobility is degraded.

The low on-resistance can be implemented by forming a channel on the SiC crystal surface, where the interface state tends to be difficult to be formed, and a higher channel mobility can be obtained. For this reason, rather than a planar type of MISFET, an SiC trench type of MISFET is employed in which a trench structure is provided in a commercially available SiC substrate of a (0001) plane or (000-1) plane, and the side wall of the trench is used as a channel, as a means for implementing the high-voltage semiconductor device with low on-resistance.

Since the channel is formed vertically relative to the substrate in the SiC trench type of MISFET, it is possible to effectively reduce the area per unit cell and the characteristic on-resistance due to a highly integrated cell structure.

Meanwhile, the SiC vertical type of power semiconductor device has a large bandgap, a high breakdown field strength, and an excellent thermal conductivity, and the like as described above. In order to make the most of such characteristics, the thickness of the drift layer is set to about 1/10 times that of the Si vertical power semiconductor device.

For this reason, in comparison with the Si trench type of MISFET, the SiC trench type of MISFET of the related art has a SiC-intrinsic problem in that, when an inverse voltage is applied, a high electric field is applied to the gate insulation film adjacent to the trench bottom, and a breakdown of the gate insulation or reliability degradation may easily occur.

In order to address such a problem, there has been studied a structure for alleviating the electric field applied to the gate insulation film of the trench bottom by providing a p-type region in the SiC portion adjoining the gate insulation film in the trench bottom.

That is, there is known a semiconductor device having a p-type region in the SiC portion adjoining the gate insulation film on the trench bottom of the SiC trench type of MOSFET.

In order to address the aforementioned problems, there is a known structure in which a trench structure is provided in a source region and a p-type region is provided under the source region so that the electric field applied to the gate insulation film on the trench bottom could be alleviated.

In addition, there is a further known semiconductor device in which the trench structure is provided in the source region of the SiC trench MOSFET, and the p-type region is provided under the source region.

Since such structures serve as a JFET region in any cases, a tradeoff exists between alleviation of the electric field intensity of the gate insulation film and the increased on-resistance caused by the parasitic resistance of the JFET.

The present embodiment has been made to address the aforementioned problems.

According to the present embodiment, a semiconductor device includes a silicon carbide layer, a trench formed in the silicon carbide layer, and a channel formed on a side-wall surface of the trench, wherein an electrical conduction direction of the channel is a horizontal direction relative to a surface of the silicon carbide layer.

It is preferable that the channel is formed in at least one of a side-wall surface, a surface of the silicon carbide layer, and a bottom surface of the trench.

It is preferable that the side-wall surface of the trench include at least one of a {10-10} plane, a {11-20} plane, and a {03-38} plane.

It is preferable that the surface of the silicon carbide layer be a {0001} plane.

it is preferable that the bottom surface of the trench be a {0001} plane.

It is preferable that the channel be a MISFET or IGBT channel.

According to the present embodiment, it is possible to implement an SiC MISFET having a channel width per unit cell area of the MISFET equal to or larger than that of the

SiC trench type MISFET of the related art and reliability higher than that of the gate insulation film of the trench bottom surface of the SiC trench type MISFET of the related art.

In addition, since the crystal plane capable of implementing a higher inversion channel mobility is also used as the channel in addition to the crystal plane used as the channel in the SiC planar type MOSFET of the related art, it is possible to implement the SiC MISFET having on-resistance lower than that of the SiC planar type MISFET of the related art.

As a result, according to the present embodiment, it is possible to provide a semiconductor device and a method of manufacturing the semiconductor device, in which low on-resistance and high reliability are obtained using SiC.

Hereinafter, embodiments will be described in more detail with reference to Examples.

### EXAMPLE 1

The semiconductor device of Example 1 includes a silicon carbide layer and a channel formed over the silicon carbide layer. The channel is provided in the side-wall surface of the trench and conducts electricity in a horizontal direction relative to the surface of the silicon carbide layer.

Here, a vertical type MISFET will be exemplarily described. Since the semiconductor device of Example 1 has the aforementioned configuration, the channel width per unit cell area increases, and the channel resistance is reduced. Therefore, it is possible to implement the MISFET having low on-resistance and a high driving performance. Since the gate insulation film does not protrude to the drift layer unlike the trench MISFET of the related art, it is possible to alleviate the electric field intensity of the gate insulation film in the vicinity of the trench bottom surface when an inversed voltage is applied, improve the reliability, and implement the MISFET having high reliability.

FIG. 1 is a perspective view illustrating a configuration of the MISFET as a semiconductor device according to the present embodiment. The MISFET 100 includes a SiC substrate 12 having first and second principal surfaces. In FIG. 1, a first principal surface is the upper surface in the drawing, and a second principal surface is the lower surface in the drawing. The SiC substrate 12 is, for example, a hexagonal crystalline 4H-SiC substrate (n′ substrate) containing nitrogen (N) as an n-type impurity in a concentration of approximately 5×10¹⁸ to 1×10¹⁹ cm⁻¹.

The SiC substrate 12 has a (0001) plane as the first principal surface. On the first principal surface, an n-type n layer 14 containing n-type impurities in a concentration of approximately 5×10¹⁵ to 2×10¹⁶ cm⁻³ is formed. The film thickness of the n′ layer 14 is set to, for example, approximately 5 to 10 μm.

A trench 40 is formed on a part of the surface of the n layer 14 and the p-well region 16. The depth of the trench 40 is set to, for example, approximately 1 μm. In addition, the width of the trench 40 is set to, for example, approximately 1 μm. A distance between the trenches 40 is set to, for example, approximately 1 μm.

By further increasing the depth of the trench 40, it is possible to increase the gate width per unit cell and reduce the channel resistance.

For example, the (11-20) plane of the side wall of the trench 40 is exposed. For example, the (0001) plane of the bottom surface of the trench 40 is exposed.

A part of the surface of the n layer 14 is provided with a p-type p-well region 16 containing p-type impurities in a concentration of approximately 1×10¹⁶ to 5×10¹⁷ cm⁻³. The depth of the p-well region 16 is set to, for example, approximately 0.6 μm.

A part of the surface of the p-well region 16 is provided with an n-type source region 16 containing p-type impurities in a concentration of approximately 1×10²⁰ cm⁻³. The depth of the source region 18 is shallower than the depth of the p-well region 16 and may be set to, for example, 0.3 μm.

The side of the n-type source region 18 as a part of the surface of the p-well region 16 is provided with a p-type p-well contact region 20 containing p-type impurities in a concentration of approximately 1×10 [symbol] to 1×10 [symbol] cm⁻³. The depth of the p-well contact region 20 is shallower than the depth of the p-well region 16 and may be set to, for example, 0.3 μm.

In addition, the gate insulation film 28 is formed over such areas and layers successively across the surface of the n layer 14 and the p-well region 16. That is, the gate insulation film 28 is formed on the (0001) plane of the SiC layer 14.

The gate insulation film 28 is a film mainly containing SiO₂ deposited, for example, using a CVD technique.

It is preferable that the thickness of the gate insulation film 28 be equal to or greater than 30 nm and equal to or smaller than 100 nm. If the thickness of the gate insulation film 28 is smaller than 30 nm, an initial breakdown voltage or reliability of the gate insulation film may be degraded. In addition, if the thickness of the gate insulation film 28 is greater than 100 nm, a driving performance of the MISFET may be degraded.

In addition, a gate electrode 30 is formed on the gate insulation film 28. For example, poly-silicon and the like may be applied to the gate electrode 30. An interlayer insulation film 32 made of, for example, a silicon oxide film is formed over the gate electrode 30.

In addition, a source/p-well common electrode 24 electrically connected to the source region 18 and the p-well contact region 20 is provided. The source/p-well common electrode 24 includes, for example, a Ni barrier metal layer 24a and an Al metal layer 24b over the barrier metal layer 24a. Alloy may be formed by virtue of reaction between the Ni barrier metal layer 24a and the Al metal layer 24b. In addition, a drain electrode 36 is formed on the second principal surface of the SiC substrate 12.

In addition, according to the present embodiment, nitrogen (N) is preferably used as the n-type impurity. However, phosphor (P), arsenic (As), or the like may be used as the n-type impurity. In addition, for example, aluminum (Al) is preferably used as the p-type impurity, but boron (B) or the like may be used.

(Manufacturing Method)

Next, a method of manufacturing the semiconductor device according to Example 1 will be described. FIGS. 2 to 4 are process perspective diagrams illustrating a method of manufacturing the semiconductor device according to the present embodiment.

First, as illustrated in FIG. 2A, a low-resistance 4H-SiC substrate 12 having a hexagonal crystalline lattice structure and a thickness of, for example, 300 μm and containing phosphor or nitrogen as n-type impurities in a concentration of approximately 1×10¹⁹ cm⁻³ is provided. In addition, a high-resistance SIC layer 14 having a thickness of approximately 10 μm and containing, for example, nitrogen as the n-type impurity in a concentration of 5×10 [symbol] cm⁻³ is grown on the (000-1) plane, which is one of the principal surfaces of the SiC substrate 12, through an epitaxial growth technique.

Then, as illustrated in FIG. 2B, the trench 40 is formed in the SiC layer 14 using a suitable mask material through a dry etching technique. The trench has a thickness of, for example, approximately 1 μm. In addition, the trench has a width of, for example, approximately 1 μm, and the interval between the trenches is set to, for example, 1 μm.

By further increasing the depth of the trench 40, it is possible to increase the gate width per unit cell and reduce the channel resistance.

Then, as illustrated in FIG. 2C, aluminum ions as the p-type impurity are implanted to the SiC layer 14 using a suitable mask material to form the p-well region 16.

Then, as illustrated in FIG. 3A, phosphor ions as the n-type impurity are implanted to the SiC layer 14 using a suitable mask material to form the source region 18. Then, as illustrated in FIG. 3B, aluminum ions as the p-type impurity are implanted to the SiC layer 14 using a suitable mask material to form the p-well contact region 20. Then, the ion-implanted impurities are activated through a thermal treatment at a temperature of, for example, approximately 1800° C.

Then, as illustrated in FIG. 3C, the oxide film 28a is formed on the (0001) plane of the SiC layer 14 through an LP-CVD technique using tetraethoxysilane (TEOS) and oxygen gases. The oxide film 28a to be formed has a thickness of, for example, 60 nm.

Then, a so-called post-oxidation annealing (POA) treatment is carried out. For example, a thermal treatment (ammonia annealing or HN, annealing) is performed in an ammonia gas atmosphere at a temperature of 1200° C., and ammonia thermal nitridation is performed. As a result, the interface state density is reduced, and a channel driving performance of the MISFET is improved.

In this case, if the POA treatment is carried out, for example, in a hydrogen (H₂) atmosphere, a vapor (H₂O) atmosphere, or the like, the interface state density is reduced due to the hydrogen termination effect. In addition, if the treatment is carried out in an ammonia (NH₃) atmosphere, a nitrous oxide (N₂O) atmosphere, a nitric monoxide (NO) atmosphere, or the like, the interface state density is reduce due to the nitrogen termination effect.

Then, as illustrated in FIG. 4A, the poly-silicon is deposited over the gate insulation film 28 and patterned using a suitable mask material so as to form the gate electrode 30.

Then, the interlayer insulation film 32, the source/p-well common electrode 24, and the drain electrode 36 are formed through the semiconductor process known in the art so as to manufacture the vertical type MISFET illustrated in FIG. 1.

In the manufacturing method according to the present embodiment, the channel width per unit cell area increases, and the channel resistance is reduced. Therefore, it is possible to implement a MISFET having low on-resistance and a high driving performance. In addition, since the gate insulation film does not protrude to the drift layer unlike the trench MISFET of the related art, it is possible to improve reliability of the gate insulation film and implement the MISFET having high reliability.

In FIGS. 5A to 5C and Table 1, there are illustrated a comparison result of the unit cell structure, the channel width per unit cell area, and the effective inversion channel mobility between the semiconductor device according to the present embodiment and the semiconductor device of the related art.

TABLE 1

| | | EXISTING | EXISTING |
|---|---|---|---|
| | EXAMPLE | STRUCTURE 1 | STRUCTURE 2 |
| | FIN TYPE | PLANAR TYPE | TRENCH TYPE |
| GATE WIDTH | 0.67 | 0.25 | 0.64 |
| PER UNIT | | | |
| VOLUME(μm) | | | |
| EFFECTIVE | 83 | 50 | 100 |
| CHANNEL | | | |
| MOBILITY | | | |
| (μeff[cm²/Vs] | | | |

The unit cell structure of the semiconductor device according to the present embodiment has a channel width per unit cell area of 0.67 μm, which is the highest value.

In addition, the effective inversion channel mobility of the semiconductor device according to the present embodiment is higher than that of the planar type MISFET illustrated in the existing structure 1 and lower than that of the trench type MISFET illustrated in the existing structure 2.

Therefore, it is possible to implement the MISFET having on-resistance lower than that of the planar type MISFET of the existing structure 1 and reliability higher than that of the trench MISFET of the existing structure 2.

### EXAMPLE 2

In the semiconductor device of Example 1, the n-type SiC substrate is used. However, in the semiconductor device of Example 2, a p-type insulated gate bipolar transistor (IGBT) is provided. Example 2 is similar to Example 1 except that the impurity type of the SiC substrate is different, and repetitive description will be omitted for brevity.

FIG. 6 is a perspective view illustrating a configuration of the IGBT as a semiconductor device according to the present embodiment. The IGBT 300 includes a SIC substrate 52 having first and second principal surfaces. In FIG. 6, the first principal surface is the upper surface in the drawing, and the second principal surface is the lower surface in the drawing. The SiC substrate 52 is a hexagonal crystalline 4H-SiC substrate (p′ substrate) containing, for example, aluminum as the p-type impurity in a concentration of approximately 5×10 [symbol] to 1×10 [symbol] cm⁻³.

In addition, a method of manufacturing the semiconductor device according to the present embodiment is similar to that of Example 1 except that the prepared SiC substrate is the hexagonal crystalline 4H-SiC substrate (p′ substrate) containing, for example, aluminum as the p-type impurity. Therefore, in the semiconductor device according to the present example, it is possible to implement the

IGBT having low on-resistance and high driving performance. In addition, since the reliability of the gate insulation film is improved, it is possible to implement the IGBT having high reliability. Therefore, it is possible to manufacture the IGBT having low on-resistance and high reliability.

(Modification)

In the aforementioned description, the trench shape has a rectangular cross-section. However, the cross-section may not be rectangular but triangular or trapezoidal. The cross-sectional shape may be appropriately designed if it satisfies a condition that the side wall or the bottom surface of the trench is formed to provide a plane having a high electric charge mobility of SiC.

(Modification)

Although some embodiments have been described hereinbefore, those embodiments are just exemplary and are not intended to limit the scope of the invention. Such embodiments may be embodied in various other forms, and various omissions, substitutions, or changes may be possible without departing from the spirit and scope of the invention. Such embodiments and modifications are construed to encompass the scope of the invention and equivalents thereof if they are similarly included in the scope or subject matter of the invention.

What is claimed is:

1. A semiconductor device comprising:
a silicon carbide layer;
a trench formed in the silicon carbide layer; and
a channel formed on at least one of a bottom of the trench, a side-wall surface, or the silicon carbide layer,
wherein an electrical conduction direction of the channel is parallel to a surface of the silicon carbide layer.

2. The semiconductor device according to claim 1,
wherein the side-wall surface of the trench includes at least one of a {10-10} plane, a {11-20} plane, and a {03-38} plane.

3. The semiconductor device according to claim 1,
wherein the surface of the silicon carbide layer is a {0001} plane.

4. The semiconductor device according to claim 1,
wherein the bottom surface of the trench is a {0001} plane.

5. The semiconductor device according to claim 1,
wherein the channel is an MISFET or IGBT channel.
